(19) United States
(12) Patent Application Publication
(10) Pub. No.: US 2019/0271728 A1
(43) Pub. Date: Sep. 5, 2019

(54) DEVICE AND METHOD FOR DETECTING A NUMBER OF ELECTROSTATIC DISCHARGES

(71) Applicant: Robert Bosch GmbH, Stuttgart (DE)

(72) Inventors: Timo Seitzinger, Eningen (DE); Franz Dietz, Willmandingen (DE)

(21) Appl. No.: 16/348,232

(22) PCT Filed: Sep. 12, 2017
(86) PCT No.: PCT/EP2017/072854

§ 371 Date: May 8, 2019

(30) Foreign Application Priority Data
Nov. 9, 2016 (DE) 10 2016 221 925.1

(51) Int. Cl. G01R 31/00; H02H 9/04; H02H 1/00

(52) U.S. Cl. CPC G01R 31/002; H02H 1/0007; H02H 9/046

(57) ABSTRACT

An apparatus for detecting a number of electrostatic discharges, comprises a discharge protection device, wherein a detection unit is disposed electrically in parallel with the discharge protection device, and the detection unit encompasses at least one memory block, the memory block having a reset input.

### FIELD

The present invention relates to an apparatus and a method for detecting a number of electrostatic discharges.

### BACKGROUND INFORMATION

Integrated circuits contain a plurality of structures made of different materials. The sensitivity of those structures to stress is greatly increasing because the structure sizes are becoming smaller and smaller.

Electrostatic discharges (ESDs) in or through the chip are one type of stress. They are produced by charge separation and charge accumulation when two surfaces of materials having different electron affinities touch one another. An electrostatic charge occurs if even a small component of a machine or a package slips.

An electrostatic charge of this kind charges components to several thousand volts. Depending on the technology, defects in components and structures can occur in modern ASICs at a voltage of as little as 1 V.

Electrostatic discharges occur comparatively frequently. In order to make possible the production and processing of the chips despite this, structures that clamp, i.e. limit, the voltage at the input of the ICs are built into ASICs.

So-called “ESD clamps” provide the accumulated charge with a low-impedance path for dissipation of the charge carriers. These sensitive structures of the ASICs are thereby protected from high voltages and currents.

Despite these ESD clamps, an electrostatic discharge signifies stress on an ASIC. ESD clamps are dimensioned as economically as possible, but already have a comparatively large area. The physical size of the ESD clamps is up to 30% of the total circuit size, and depends on the intensity of the electrostatic discharge assumed for the circuit. For that reason, some ESD structures can withstand only a limited number of discharges and then can no longer adequately protect the ASIC. The ESD clamps are moreover dimensioned so that the ASIC is protected from overvoltage only within the context of its specification. An unexpectedly high voltage applied briefly to the ASIC can therefore still destroy components.

The document F. Altolaguirre and M. Ker (2013), “Power-Rail ESD Clamp Circuit with Diode-String ESD Detection to Overcome the Gate Leakage Current in a 40-nm CMOS Process,” IEEE Transactions on Electron Devices, Vol. 60, Issue 10, pp. 3500-3507, describes the detection of an electrostatic charge in order to allow activation of a discharge protection circuit in the context of a discharge having a lower switch-on current. The area of the clamp can thereby be reduced.

The document M. Ker et al. (2010), “On-Chip ESD Detection Circuit for System-Level ESD Protection Design,” 10th IEEE Conference on Solid-State and Integrated Circuit Technology (ICSICT), pp. 1584-1587, describes an ESD event or transient signal that is detected during operation so that the circuit of a TFT-LC display can be brought into a safe state.

The document H. Sung et al. (2010), “Design of Toroidal Current Probe Embedded in Multi-Layer Printed Circuit Boards for Electrostatic Discharge (ESD) Detection,” IEEE Electrical Design of Advanced Package and Systems Symposium, pp. 1-4, describes the fact that an ESD event can be detected by way of an integrated electrical coil. This is confirmed by a measurement using a clamp meter.

The document W. Kuhn and R. Eatinger (2011), “Built-in Self-Test in Integrated Circuits—ESD Event Mitigation and Detection,” Masters Thesis at Kansas State University, graduated 2011, describes the detection of an ESD event or transient signal during operation by way of the melting of a kind of fuse. For this, a thin lead that is destroyed under ESD stress is connected in parallel with the ESD coupling diodes. That destruction represents a stored information item, since it is not reversible. A detection function therefore cannot be guaranteed under all conditions. Destruction of the thin lead connected in parallel can negatively influence the ASIC.

It is disadvantageous that the detection of an electrostatic charge can be carried out only once. That means that this method is not reliable, since it can detect only a single discharge. The ASIC can suffer damage in the context of a further electrostatic discharge. A large area on the chip is moreover required.

An object of the present invention is to reliably detect the number of electrostatic discharges.

### SUMMARY

An example apparatus for detecting a number of electrostatic discharges in accordance with the present invention encompasses a discharge protection device. According to the present invention, a detection unit is disposed or connected electrically in parallel with the discharge protection device. The detection unit encompasses at least one memory block, and the memory block has a reset input.

The advantage here is that the detection unit can be used repeatedly and the number of memory cells required is small, so that the detection unit occupies little space.

In a refinement of the present invention, the detection unit has an energy block that encompasses a linear controller.

It is advantageous in this context that the charge quantity that is delivered to the memory block is kept constant. In other words, the voltage at the memory block is limited.

In a further embodiment of the present invention, the detection unit has a switch. The switch encompasses in particular an NMOS transistor that is connected as or functions as a diode.

The advantage here is that an electrostatic discharge is detected only above a specific voltage swing.

In a refinement of the present invention, the switch is disposed between the discharge protection device and the memory block.

In a further embodiment of the present invention, the energy block has a first output and a second output, a capacitor being disposed between the first output and the second output.

The advantage here is that a capacitor having a small area can be used.

In a refinement of the present invention, the memory block has a first terminal and a second terminal, a timer being disposed between the first terminal and the second terminal.

It is advantageous in this context that the memory cell can be written to. In other words, a discharge of the programming pin takes place.

In a further embodiment of the present invention, the detection unit has an evaluation unit.

The advantage here is that the memory cell can be read out during the electrostatic discharge pulse.

In a refinement of the present invention, the detection unit encompasses a counter.

It is advantageous in this context that the number of electrostatic discharge pulses that occur at the protected pin can be detected by the discharge protection device.

In a further embodiment of the present invention, the detection unit encompasses at least one bistable flip-flop.

The advantage here is that the memory cell is evaluated with zero current.

The method according to the present invention for detecting a number of electrostatic discharges encompasses detection of a voltage that is present at a discharge protection device. Depending on the voltage that is detected, an input voltage of the detection unit is generated. A switching of the detection unit becomes activated, and at least one memory cell of the memory block is written to. The number of electrostatic discharges is detected.

It is advantageous in this context that the number of electrostatic discharges can be detected in simple fashion.

In a refinement of the present invention, an evaluation unit reads out the state of at least one memory cell of the memory block during the occurrence of an electrostatic discharge pulse.

The advantage here is that no buffer capacitors are needed in order to store the energy of the electrostatic discharge pulse, so that the space requirement of the detection unit is low.

Further advantages are evident from the description below of exemplifying embodiments.

### BRIEF DESCRIPTION OF THE DRAWINGS

The present invention will be explained below with reference to preferred embodiments and the figures.

FIG. 1 is a block diagram of an apparatus for detecting a number of electrostatic discharges.

FIG. 2 shows the apparatus for detecting the number of electrostatic discharges, with an equivalent circuit diagram of the energy block,

FIG. 3 is a block diagram of the apparatus for detecting the number of electrostatic discharges, having an evaluation unit.

FIG. 4 is a block diagram of the apparatus for detecting two electrostatic discharges.

FIG. 5 shows a circuit for generating a read signal that is generated with a time offset from the supply voltage.

FIG. 6 shows a level shifter.

FIG. 7 shows a method for detecting a number of electrostatic discharges.

### DETAILED DESCRIPTION OF EXAMPLE EMBODIMENTS

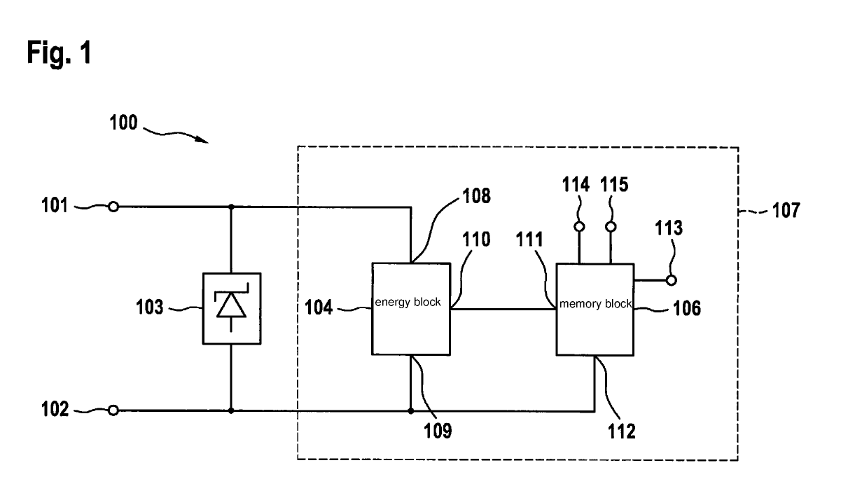

FIG. 1 is a block diagram of an apparatus 100 for detecting a number of electrostatic discharges. Apparatus 100 encompasses a first terminal 101 and a second terminal 102 which are electrically connected to a discharge protection device 103. Discharge protection device 103 protects at least one component terminal of an ASIC from overvoltage, for example that component terminal of the ASIC which is electrically conductively connected to first terminal 101. In this case a ground path of the ASIC typically is electrically conductively connected to second terminal 102. A detection unit 107 is disposed or connected electrically in parallel with discharge protection device 103. This means that detection unit 107 recognizes or detects electrostatic discharge pulses. Detection unit 107 encompasses an energy block 104 and a memory block 106, the memory block having at least one memory cell. Energy block 104 encompasses a first input 108, a second input 109, and a first output 110. A second input 109 of energy block 104 is connected, for example, to ground. Memory block 106 encompasses a first input 111, a second input 112, a reset input 113, a first output 114, and a second output 115. Second input 112 of memory block 106 is connected, for example, to ground. First output 110 of energy block 104 is electrically conductively connected to first input 111 of memory block 106. First output 114 of memory block 106 is inverted with respect to second output 115 of memory block 106. Alternatively, first output 114 of memory block 106 is not inverted with respect to second output 115 of the memory block.

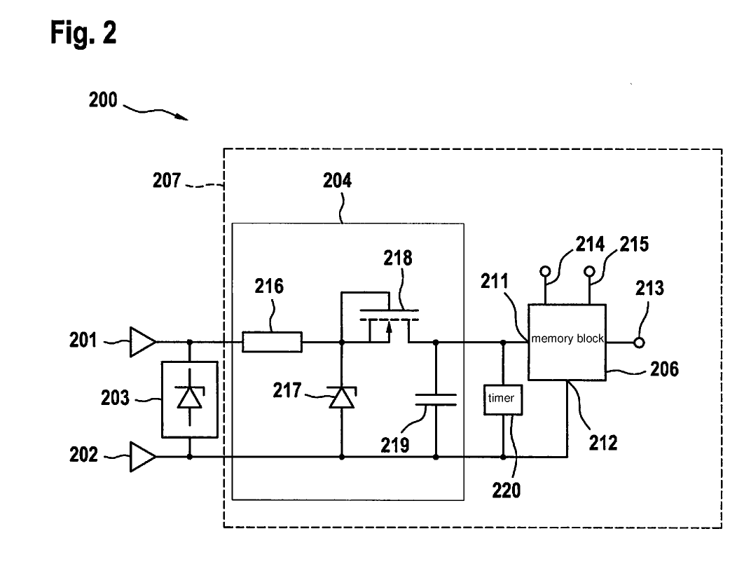

FIG. 2 shows the apparatus for detecting the number of electrostatic discharges, with an equivalent circuit diagram of energy block 204. Energy block 204 is disposed between discharge protection device 203 and memory block 206, memory block 206 encompassing, by way of example, one memory cell. Energy block 204 encompasses a linear regulator that has a resistor 216 and a Zener diode 217. Energy block 204 additionally has a switching 218 and a capacitor 219. Switching 218 encompasses, for example, an NMOS transistor that is wired or interconnected as a diode. Resistor 216 limits an output current of the linear regulator. Zener diode 217 limits a capacitor voltage of capacitor 219. Capacitor 219 has a small inherent area and is used to stabilize the voltage during a memory operation. The purpose of the linear regulator is to furnish, for the time period during which an electrostatic discharge pulse occurs, a predefined voltage at first input 211 of memory block 206. A voltage of at least 10 V is typically needed in order to program the memory cell or memory block. To allow the memory cell to be programmed or written to, the predefined voltage must be present for a specific time period at first input 211 of memory block 206. This is achieved with the aid of a timer 220 that is disposed between first input 211 of memory block 206 and second input 212 of memory block 206. The specific time period that is set by way of timer 220 is, for example, 10 ms. Memory block 206 encompasses a reset input 213 that can erase the memory cell of memory block 206. First input 211 of memory block 206, as well as the reset input, indicate the memory state of the memory cell. If a logical “1” is present at the first input of the memory cell, the memory cell is then programmed. If a logical “1” is present at the reset input, the memory cell is then not written to. These two inputs always have inverted states with respect to one another. Memory block 206 furthermore encompasses a first output 214 and a second output 215 which output or indicate, or represent, the state of memory block 206. If memory block 206 encompasses several memory cells, memory block 206 has either one shared reset input for all memory cells of the memory block, or one respective reset input for each memory cell.

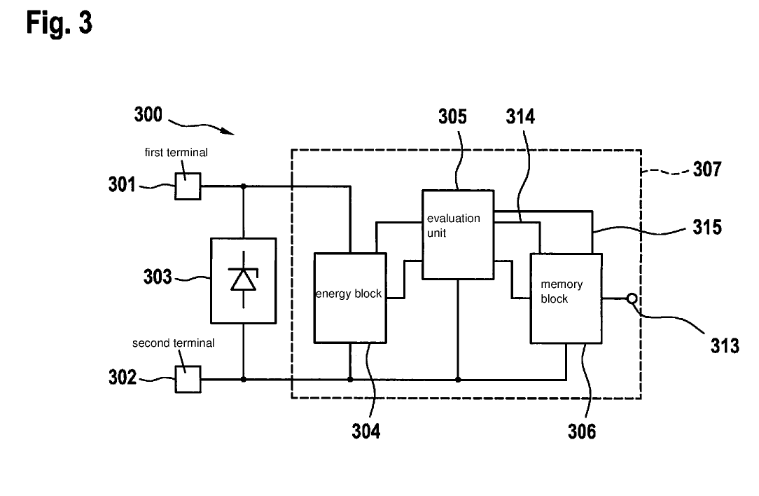

FIG. 3 is a block diagram of apparatus 300 for detecting the number of electrostatic discharges, having an evaluation unit 305. Apparatus 300 encompasses a first terminal 301 and a second terminal 302, which are electrically connected to a discharge protection device 303. A detection unit 307 is connected electrically in parallel with discharge protection device 303. Detection unit 307 encompasses an energy block 304, an evaluation unit 305, and a memory block 306. In this exemplifying embodiment, memory block 306 encompasses at least two memory cells. The purpose of evaluation unit 305 is to evaluate the memory cells during an electrostatic discharge pulse. In other words, evaluation unit 305 can read out the state of the memory cells during an electrostatic discharge pulse. Because several memory cells are present, it is possible to ascertain the number of electrostatic discharge pulses.

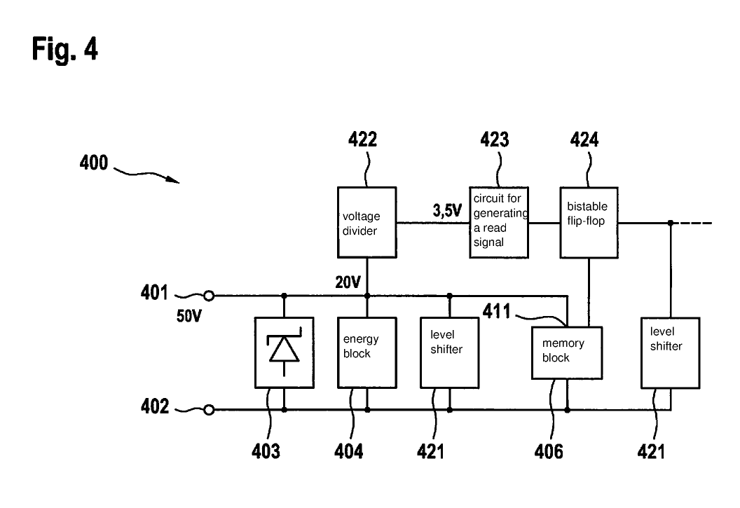

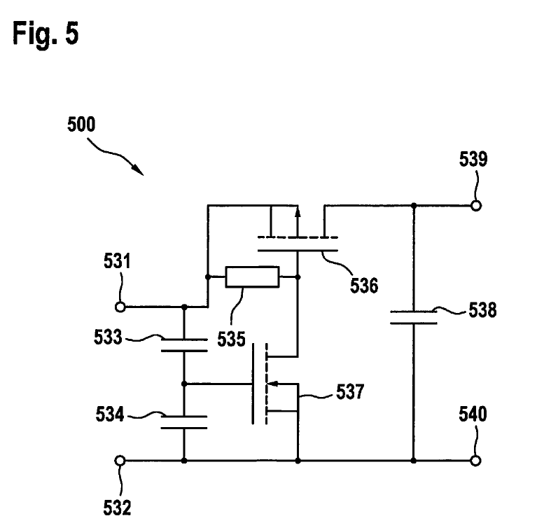

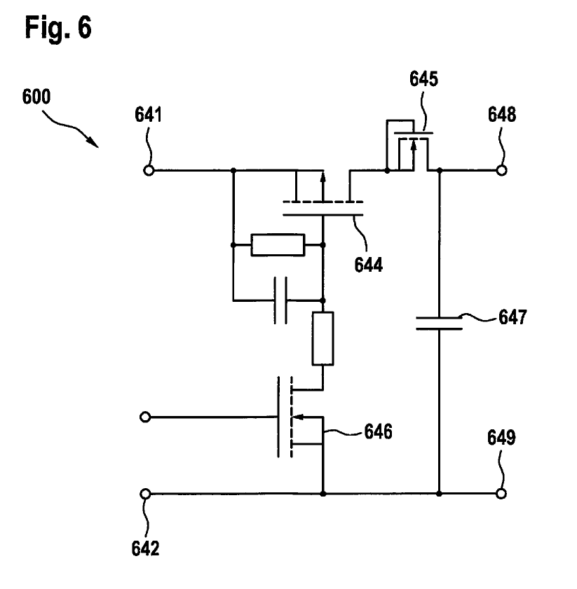

FIG. 4 is a block diagram of apparatus 400 for detecting two electrostatic discharges. Apparatus 400 has a first input 401, a second input 402, a discharge protection device 403, and an energy block 404 and a memory block 406. In this exemplifying embodiment memory block 406 encompasses two memory cells. Apparatus 400 furthermore has a level shifter 421 that is connected in parallel with the first output of energy block 404 and with the second output of energy block 404. Level shifter 421 furnishes the programming voltage for first input 411 of memory block 406. The term “programming voltage” is understood here to mean the voltage that is necessary in order to allow a memory cell to be written to. Apparatus 400 furthermore has a voltage divider 422 for generating a voltage for the evaluation unit. The voltage of evaluation unit is in the range of <5 V. Apparatus 400 additionally encompasses a circuit 423 for generating a read signal, and a bistable flip-flop 424 for evaluating the state of a memory cell. As already shown in FIG. 2, energy block 404 encompasses a resistor, a Zener diode, a MOSFET transistor connected as a diode, and a capacitor. Energy block 404 converts the voltage that is present at discharge protection device 402 during an ESD pulse into a lower voltage so that the memory cells of memory block 406 can be programmed. The programming voltage is typically 20 V. The output of energy block 404 is connected to a voltage divider 422 for generating the supply voltage of the evaluation unit, the evaluation unit being implemented with the aid of a bistable flip-flop. This means that the evaluation unit controls the programming and evaluation of the memory cells. The evaluation unit requires, for example, a supply voltage of, in particular, 3.5 V. When the evaluation unit is supplied with this supply voltage, a voltage which generates a logic signal that indicates the state of the memory cell is then applied to a read input of the evaluation unit. Upon readout of the memory cell, the logic signal that represents a read signal must be applied to the flip-flop with a time offset after the supply voltage. This offset in time is generated with the aid of circuit 423, which is described in more detail in FIG. 5. Thanks to the use of the flip-flop, the memory cells are evaluated in almost zero-current fashion. This means that there is no load on detection unit 407, i.e. no current is drawn out of the detection unit. By way of the logic signals of the flip-flop which are generated, the circuit controls whether the evaluated memory cell is to be programmed or whether a further memory cell needs to be evaluated. The first memory cell, not yet written to, is permanently programmed by way of the programming voltage generated by the energy block. Evaluation of a further memory cell requires a level shifter circuit 421 that is shown in FIG. 6.

FIG. 5 shows the equivalent circuit diagram of block 423 of FIG. 4. The circuit has a first input 531, a second input 532, a first capacitor 533, a second capacitor 534, a resistor 535, a PMOS transistor 536, an NMOS transistor 537, a capacitor 538, a first output 539, and a second output 540. With the aid of first capacitor 533 and second capacitor 534, which are connected to the input of the circuit, it is possible to adjust the length of time needed, in the context of a rising supply voltage at NMOS transistor 537, to switch PMOS transistor 536. In the switched state, PMOS transistor 536 connects the supply voltage to the read input of the evaluation circuit.

FIG. 6 shows a level shifter circuit 600 for applying the programming voltage to a further memory cell once a first memory cell has been evaluated. Level shifter circuit 600 encompasses a first input 641, a second input 642, a PMOS transistor 644, an NMOS transistor 645 wired as a diode, an NMOS transistor 646 for applying control to PMOS transistor 644, a filter capacitor 647, a first output 648, and a second output 649. In the subsequent programming operation, the further memory cell is written to. A fast voltage edge that is applied to first input 641 of level shifter 600 causes a coupling of charge carriers via the blocked PMOS transistor 644, so that a filter capacitor 647 is needed at first output 648 of level shifter 600 in order to filter that high-frequency interference. NMOS transistor 645 wired as a diode ensures that the programming voltage is discharged via filter capacitor 647, at the earliest, only after a predefined time.

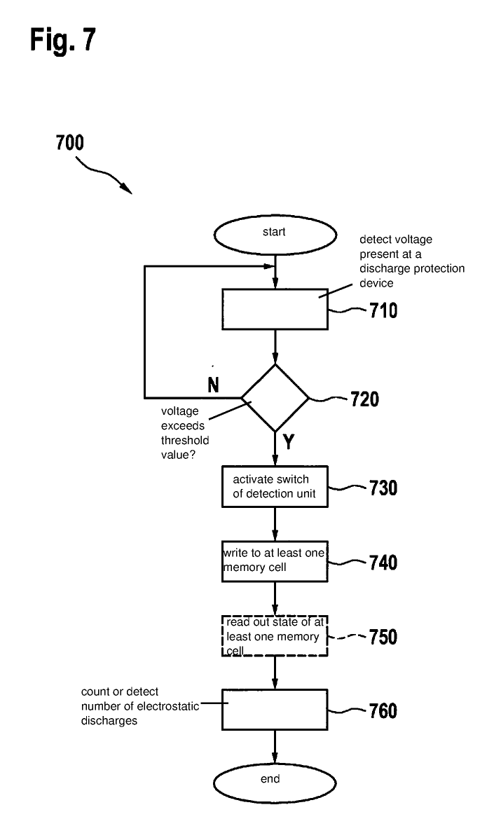

FIG. 7 shows a method 700 for detecting a number of electrostatic discharges. Method 700 begins with detection 710 of a voltage that is present at a discharge protection device. If the voltage exceeds a threshold value that is predefined by the discharge protection device, an input voltage is then generated in a subsequent step 720 and is applied to the detection unit. In other words, upon occurrence of an electrostatic discharge pulse, the discharge protection device reacts so that an input voltage for the detection unit is furnished. The input voltage is reduced in the energy block, for example by way of a voltage divider, so that the voltage within the detection unit protects, or does not destroy, the individual components. The discharge protection device typically reacts above a threshold value of approximately 50 V. That voltage is reduced by way of the discharge protection device to a voltage value of, for example, 20 V. If the threshold value is not exceeded, the method terminates or begins again with step 710. In a subsequent step 730, the switching of the detection unit becomes activated if sufficient voltage is present at the switching. In other words, the remainder of the detection unit, i.e., at least the memory block, becomes activated. In a subsequent step 740, at least one memory cell of the memory block is written to. In a subsequent step 760, the number of electrostatic discharges is counted or detected, for example by way of a control unit.

In an optional step 750 that is executed between step 740 and step 760, an evaluation unit can read out the state of at least one memory cell of the memory block during the occurrence of an electrostatic discharge pulse. In other words, all the switching or evaluation operations occur during the occurrence of the electrostatic discharge pulse, which typically has a duration of 100 ns. Optionally, the evaluation unit can select, depending on the memory state of the memory cells that are present, whether, or which of, the memory cells are to be programmed next or which are to be erased. The memory cell is erased by way of the reset input. Erasure is effected, for example, by the evaluation unit in the normal operating state of the ASIC, once error-free functioning of the ASIC after a detected ESD event has been checked. The check can be made, for example, by way of an additional test routine of a control device. Because the memory cells can be both programmed and erased, the memory cells can be evaluated in coded fashion, e.g. using binary code. All memory cells are programmed, read out, or erased during the electrostatic discharge pulse.

1-11. (canceled)

12. An apparatus for detecting a number of electrostatic discharges, comprising:
a discharge protection device; and
a detection unit disposed electrically in parallel with the discharge protection device, the detection unit including at least one memory block, the memory block having a reset input.

13. The apparatus as recited in claim 12, wherein the detection unit has an energy block that includes a linear controller.

14. The apparatus as recited in claim 12, wherein the detection unit has a switch.

15. The apparatus as recited in claim 14, wherein the switch is an NMOS transistor.

16. The apparatus as recited in claim 14, wherein the switch is disposed between the discharge protection device and the memory block.

17. The apparatus as recited in claim 13, wherein the energy block has a first output and a second output, a capacitor being disposed between the first output and the second output.

18. The apparatus as recited in claim 12, wherein the memory block has a first terminal and a second terminal, a timer being disposed between the first terminal and the second terminal.

19. The apparatus as recited in claim 12, wherein the detection unit has an evaluation unit.

20. The apparatus as recited in claim 12, wherein the detection unit includes a counter.

21. The apparatus as recited in claim 12, wherein the detection unit includes at least one bistable flip-flop.

22. A method for detecting a number of electrostatic discharges, comprising:
detecting a voltage that is present at a discharge protection device;
generating an input voltage of the detection unit depending on the detected voltage;
activating a switch of the detection unit;
writing to at least one memory cell of the memory block; and
detecting a number of electrostatic discharges.

23. The method as recited in claim 22, wherein an evaluation unit reads out the state of at least one memory cell of the memory block during the occurrence of an electrostatic discharge pulse.
